(19) United States
(12) Patent Application Publication
(10) Pub. No.: US 2024/0105459 A1
(43) Pub. Date: Mar. 28, 2024

(54) METHOD FOR MANUFACTURING SEMICONDUCTOR ELEMENT

(71) Applicant: NICHIA CORPORATION, Anan-shI (JP)

(72) Inventor: Naoki MUSASHI, Anan-shi (JP)

(73) Assignee: NICHIA CORPORATION, Anan-shi (JP)

(21) Appl. No.: 18/467,920

(22) Filed: Sep. 15, 2023

(30) Foreign Application Priority Data
Sep. 27, 2022 (JP) 2022-153616
Aug. 25, 2023 (JP) 2023-137476

(51) Int. Cl. H01L 21/308; H01L 33/00

(52) U.S. Cl. CPC H01L 21/3081; H01L 33/0075

(57) ABSTRACT

A method for manufacturing a semiconductor element includes preparing a semiconductor structure body that includes a p-side layer and an n-side layer; forming a first carbon film on the p-side layer by vapor deposition, the vapor deposition utilizing carbon ions generated by an arc discharge without introducing a gas to a discharge space, the discharge space being a vacuum; forming a second carbon film on the n-side layer by the vapor deposition; removing the first carbon film; and removing the second carbon film. A first bias voltage of the forming during the first carbon film on the p-side layer is higher than a second bias voltage of the forming during the second carbon film on the n-side layer.

### CROSS-REFERENCE TO RELATED APPLICATION

This application claims priority to Japanese Patent Application No. 2022-153616, filed on Sep. 27, 2022, and Japanese Patent Application No. 2023-137476, filed on Aug. 25, 2023, the disclosures of which are hereby incorporated by reference in their entireties.

### BACKGROUND

The disclosure relates to a method for manufacturing a semiconductor element.

For example, Japanese Patent Publication No. S62-252944 discusses the use of DLC (Diamond Like Carbon) as a dry etching mask of a semiconductor substrate.

### SUMMARY

An object of the present disclosure is to provide a method for manufacturing a semiconductor element in which electrical resistances of a p-side layer and an n-side layer can be easily reduced.

In an embodiment of the present disclosure, a method for manufacturing a semiconductor element includes preparing a semiconductor structure body, the semiconductor structure body including a p-side layer and an n-side layer; forming a first carbon film on the p-side layer by vapor deposition, the vapor deposition utilizing carbon ions generated by an arc discharge without introducing a gas to a discharge space, the discharge space being a vacuum; forming a second carbon film on the n-side layer by the vapor deposition; removing the first carbon film; and removing the second carbon film. A first bias voltage of the forming of the first carbon film on the p-side layer is higher than a second bias voltage of the forming of the second carbon film on the n-side layer.

According to the present disclosure, a method for manufacturing a semiconductor element in which electrical resistances of a p-side layer and an n-side layer can be easily reduced can be provided.

### BRIEF DESCRIPTION OF THE DRAWINGS

FIGS. 1 to 9 are schematic cross-sectional views for describing processes of a method for manufacturing a semiconductor element of an embodiment; and

FIGS. 10 to 12 are schematic cross-sectional views for describing processes of a method for manufacturing a semiconductor element according to a modification of the embodiment.

### DETAILED DESCRIPTION

Embodiments will now be described with reference to the drawings. Unless specifically stated, the dimensions, materials, shapes, relative arrangements, and the like of the components according to the embodiments are not intended to limit the scope of the embodiments to those only, and are merely illustrative examples. The sizes, positional relationships, and the like shown in the drawings may be exaggerated for clarity of description. In the following description, the same names and reference numerals indicate the same or similar members, and a detailed description is omitted as appropriate. End views that show only cross sections may be used as cross-sectional views.

In the following description, terms that indicate specific directions or positions (e.g., “above,” “below,” and other terms including or related to such terms) may be used. Such terms, however, are used merely for better understanding of relative directions or positions when referring to the drawings. As long as the relationships are the same, the relative directions or positions according to terms such as “above,” “below,” etc., used when referring to the drawings may not necessarily have the same arrangements in drawings, actual products, and the like outside the disclosure. In the specification, when assuming that there are, for example, two members, the positional relationship expressed as “above” (or “below”) includes the case where the two members are in contact, and the case where the two members are not in contact so that one of the members is positioned above (or below) the other member. Unless specifically stated in the specification, a member covering a covered object includes the case where the member contacts the covered object and directly covers the covered object, and the case where the member indirectly covers the covered object without contacting the covered object.

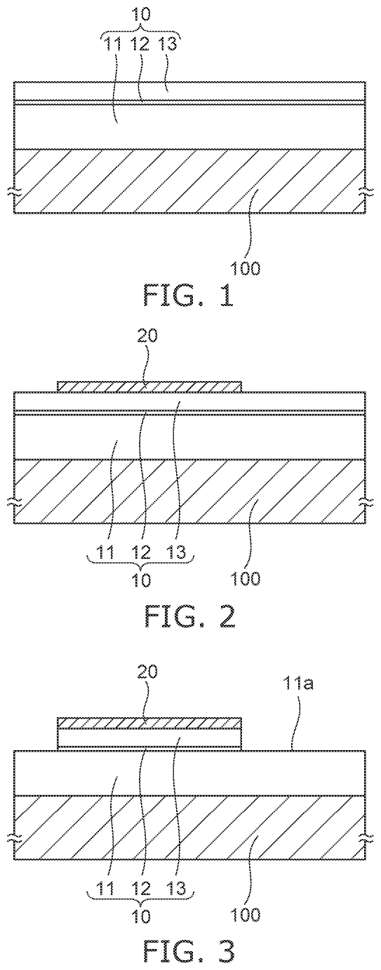

A method for manufacturing a semiconductor element of an embodiment will now be described with reference to FIGS. 1 to 9.

As shown in FIG. 1, the method for manufacturing the semiconductor element of the embodiment includes a process of preparing a semiconductor structure body 10. The semiconductor structure body 10 is made of a nitride semiconductor. In the specification, “nitride semiconductor” includes, for example, all compositions of semiconductors of the chemical formula InₓAl_{y}Ga_{1-x-y}N (0≤x≤1, 0≤y≤1, and x+y≤1) for which the composition ratios x and y are changed within the ranges respectively. “Nitride semiconductor” further includes Group V elements other than N (nitrogen) in the chemical formula above, various elements added to control various properties such as the conductivity type, etc.

The semiconductor structure body 10 includes a p-side layer 13 and an n-side layer 11. A method for manufacturing a light-emitting element as a semiconductor element is described in the embodiment. Accordingly, the semiconductor structure body 10 further includes an active layer 12 positioned between the n-side layer 11 and the p-side layer 13. The active layer 12 is a light-emitting layer that emits light and has, for example, a MQW (Multiple Quantum well) structure including multiple barrier layers and multiple well layers. For example, the active layer 12 emits light having a peak wavelength of not less than 210 nm and not more than 580 nm. The n-side layer 11 includes a semiconductor layer including an n-type impurity. The p-side layer 13 includes a semiconductor layer including a p-type impurity.

It is sufficient for the semiconductor structure body 10 to include at least the p-side layer and the n-side layer; the active layer emitting light may be omitted from the semiconductor structure body 10. In other words, the semiconductor element is not limited to a light-emitting element and may be a diode element, a transistor element, etc.

In the process of preparing the semiconductor structure body 10, for example, the semiconductor structure body 10 is formed on a substrate 100 by MOCVD (Metal Organic Chemical Vapor Deposition). The substrate 100 can include, for example, an insulating substrate of sapphire or spinel (MgAl₂O₄) having one of a C-plane, an R-plane, or an A-plane as a major surface. A conductive substrate of SiC (including 6H, 4H, and 3C), ZnS, ZnO, GaAs, Si, etc., may be used as the substrate 100. The n-side layer 11, the active layer 12, and the p-side layer 13 are formed in this order on the substrate 100.

The semiconductor structure body 10 includes, for example, gallium nitride. A gas including at least trimethylgallium and ammonia can be used as the raw material gas when forming the semiconductor structure body 10 on the substrate 100. Triethylgallium may be used instead of trimethylgallium. When forming the n-side layer 11, the n-side layer 11 is doped with, for example, silicon as an n-type impurity. Germanium may be used as the n-type impurity. When forming the p-side layer 13, the p-side layer 13 is doped with, for example, magnesium as a p-type impurity.

In the process of preparing the semiconductor structure body 10, the semiconductor structure body 10 that is formed on the substrate 100 may be prepared by procurement.

After the process of preparing the semiconductor structure body 10, the method for manufacturing the semiconductor element of the embodiment includes a process of forming a first carbon film 20 on the p-side layer 13 as shown in FIG. 2.

The first carbon film 20 has an amorphous structure including carbon in sp³ hybridized orbitals and carbon in sp² hybridized orbitals. The first carbon film 20 has diamond characteristics caused by carbon in sp³ hybridized orbitals and graphite characteristics caused by carbon in sp² hybridized orbitals.

The first carbon film 20 is formed on the p-side layer 13 by vapor deposition utilizing carbon ions generated by arc discharge without introducing a gas to a discharge space that is a vacuum. For example, the first carbon film 20 is formed by a FCVA (Filtered Cathodic Vacuum Arc) technique. For example, an arc discharge is generated on a carbon material (e.g., an ingot of graphite) placed in a vacuum of not more than 5×10⁻⁵ Torr, and favorably not more than 2×10⁻⁵ Torr to generate plasma including anionized carbon. The carbon ions are guided through the vacuum chamber toward the semiconductor structure body 10 to which a negative bias voltage is applied and collide with the p-side layer 13 of the semiconductor structure body 10. Thereby, the first carbon film 20 is formed on the p-side layer 13. A first carbon film 20 that includes almost no hydrogen can be formed by utilizing carbon ions generated by an arc discharge without introducing a gas to a discharge space that is a vacuum. The hydrogen composition ratio of the first carbon film 20 is not more than 1%.

The first carbon film 20 that includes almost no hydrogen has many dangling bonds that are not terminated with hydrogen. By forming such a first carbon film 20 on the p-side layer 13, it is considered that the hydrogen that was incorporated into the p-side layer 13 by the raw material gas bonds to the dangling bonds of the first carbon film 20 and desorbs from the p-side layer 13.

The hydrogen that is included in the p-side layer 13 makes it difficult to activate the magnesium, i.e., the p-type impurity, in the p-side layer 13. Therefore, by the hydrogen desorbing from the p-side layer 13, the magnesium in the p-side layer 13 can be activated, and the electrical resistance of the p-side layer 13 can be reduced.

The first carbon film 20 that is formed to reduce the electrical resistance of the p-side layer 13 can be used as a first mask described below to pattern the semiconductor structure body 10. Accordingly, the processes can be fewer than when another mask for patterning the semiconductor structure body 10 is formed.

As shown in FIG. 3, the method for manufacturing the semiconductor element of the embodiment includes a process of etching the p-side layer 13 and the active layer 12 by using the first carbon film 20 formed on the p-side layer 13 as the first mask to expose a portion 11a of the n-side layer 11 from under the p-side layer 13 and the active layer 12. For example, the portion 11a of the n-side layer 11 is exposed from under the p-side layer 13 and the active layer 12 by removing the p-side layer 13 and the active layer 12 by dry etching using a gas including chlorine. For example, RIE (Reactive Ion Etching) is an example of the dry etching when removing the p-side layer 13 and the active layer 12.

In the process of forming the first carbon film 20 on the p-side layer 13, the bias voltage applied to the semiconductor structure body 10 side is taken as a first bias voltage. In the process of forming the first carbon film 20, the ratio of carbon in sp³ hybridized orbitals in the first carbon film 20 can be set to be greater than the ratio of carbon in sp² hybridized orbitals in the first carbon film 20 by the control of the first bias voltage. For example, the ratio of carbon in sp³ hybridized orbitals in the first carbon film 20 can be set to be greater than the ratio of carbon in sp² hybridized orbitals by setting the first bias voltage to be not more than −40 V, and favorably not more than −60 V. For example, the ratio of carbon in sp³ hybridized orbitals and the ratio of carbon in sp² hybridized orbitals can be measured by micro-Raman spectroscopy.

When the ratio of carbon in sp³ hybridized orbitals is greater than the ratio of carbon in sp² hybridized orbitals in the first carbon film 20, the first carbon film 20 has stronger characteristics of diamond than graphite and the hardness of the first carbon film 20 is greater than when the ratio of carbon in sp³ hybridized orbitals is less than the ratio of carbon in sp² hybridized orbitals. Therefore, the first carbon film 20 is not easily etched when the first carbon film 20 is used as the first mask. Accordingly, the first carbon film 20 can be formed thinly when the first carbon film 20 is used as the first mask, and the time of the process of forming the first carbon film 20 can be reduced. For example, the etching rate of the first carbon film 20 can be not more than 1/10 of the etching rate of gallium nitride. For example, the thickness of the first carbon film 20 can be not less than 30 nm and not more than 500 nm.

After the process of etching the p-side layer 13 and the active layer 12 by using the first carbon film 20 as the first mask, the method for manufacturing the semiconductor element of the embodiment includes a process of removing the first carbon film 20. For example, the first carbon film 20 can be removed by ashing using oxygen plasma. By removing the first carbon film 20 by ashing using oxygen plasma, for example, the first carbon film 20 can be removed more easily than when the first carbon film 20 is removed by blasting.

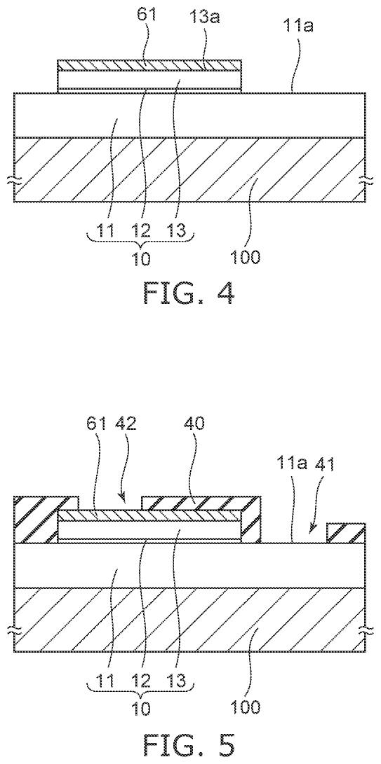

After the process of removing the first carbon film 20, the method for manufacturing the semiconductor element of the embodiment includes a process of forming a first p-side electrode 61 on the p-side layer 13 as shown in FIG. 4. The first p-side electrode 61 contacts a surface 13a of the p-side layer 13 and is electrically connected with the p-side layer 13.

As described above, hydrogen of the p-side layer 13 easily desorbs from the surface 13a in contact with the first carbon film 20; and the electrical resistance of the surface 13a of the p-side layer 13 is easily reduced. Accordingly, according to the embodiment, the contact resistance between the first p-side electrode 61 and the surface 13a of the p-side layer 13 can be easily reduced.

After the process of forming the first p-side electrode 61, the method for manufacturing the semiconductor element of the embodiment includes the process of forming an insulating film 40 as shown in FIG. 5. The insulating film 40 is, for example, a silicon oxide film or a silicon nitride film. The insulating film 40 covers the semiconductor structure body 10 and the first p-side electrode 61. The insulating film 40 includes a first opening 41 that is positioned on the portion 11a of the n-side layer 11, and a second opening 42 that is positioned on the first p-side electrode 61. The portion 11a of the n-side layer 11 is exposed from the insulating film 40 in the first opening 41. The first p-side electrode 61 is exposed from the insulating film 40 in the second opening 42.

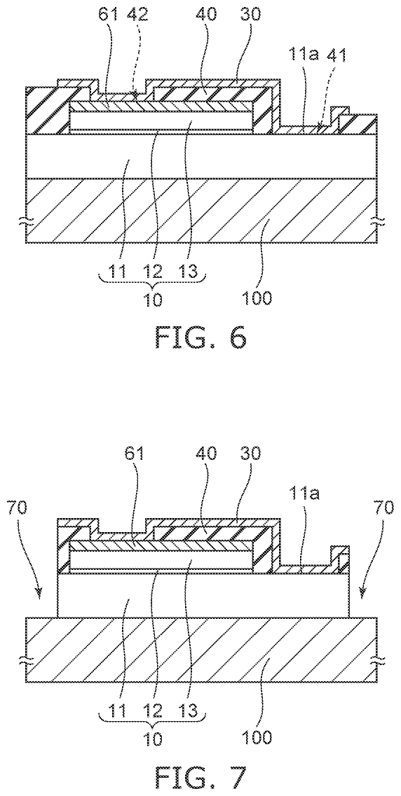

After the process of forming the insulating film 40, the method for manufacturing the semiconductor element of the embodiment includes a process of forming a second carbon film 30 as shown in FIG. 6.

The second carbon film 30 is formed on the n-side layer 11. In the example shown in FIG. 6, the second carbon film 30 is formed on the portion 11a of the n-side layer 11 exposed from the p-side layer 13 and the active layer 12. The second carbon film 30 also is continuously formed above the p-side layer 13 and on the portion 11a of the n-side layer 11. The second carbon film 30 contacts the portion 11a of the n-side layer 11 in the first opening 41. The second carbon film 30 contacts the first p-side electrode 61 in the second opening 42.

The second carbon film 30 has an amorphous structure including carbon in sp³ hybridized orbitals and carbon in sp² hybridized orbitals. The second carbon film 30 has diamond characteristics caused by carbon in sp³ hybridized orbitals and graphite characteristics caused by carbon in sp² hybridized orbitals.

Similarly to the first carbon film 20, the second carbon film 30 is formed by vapor deposition utilizing carbon ions generated by an arc discharge without introducing a gas to a discharge space that is a vacuum. The second carbon film 30 that includes almost no hydrogen can be formed by utilizing carbon ions generated by an arc discharge without introducing a gas to a discharge space that is a vacuum. The hydrogen composition ratio of the second carbon film 30 is not more than 1%.

In the process of forming the second carbon film 30 on the n-side layer 11, the bias voltage applied to the semiconductor structure body 10 side is taken as a second bias voltage. According to the embodiment, the first bias voltage in the process of forming the first carbon film 20 is higher than the second bias voltage in the process of forming the second carbon film 30. For example, the first bias voltage is not less than −40 V and not more than −10 V, and the second bias voltage is not less than −200 V and not more than −140 V.

Because the first and second bias voltages both are negative voltages and the first bias voltage is higher than the second bias voltage, the attraction energy to the semiconductor structure body 10 of the carbon ions which are cations is greater when forming the second carbon film 30 than when forming the first carbon film 20. It is therefore considered that carbon is incorporated into the surface of the portion 11a of the n-side layer 11 in the process of forming the second carbon film 30. It is considered that, as a result, a portion of the gallium inside the n-side layer 11 that includes gallium nitride is replaced with carbon, and carbon acts as an n-type impurity. It is therefore considered that the electrical resistance of the n-side layer 11 can be reduced by forming the second carbon film 30 on the n-side layer 11 with the second bias voltage described above. In the example shown in FIG. 6, the electrical resistance of the surface of the portion 11a of the n-side layer 11 exposed from the insulating film 40 in the process of forming the second carbon film 30 can be easily reduced.

The attraction energy to the semiconductor structure body 10 of the carbon ions when forming the first carbon film 20 is less than when forming the second carbon film 30, and so carbon is not easily incorporated into the surface of the p-side layer 13. Accordingly, the carbon does not easily act as an n-type impurity of the p-side layer 13 when forming the first carbon film 20.

The second carbon film 30 that is formed to reduce the electrical resistance of the n-side layer 11 can be used as a second mask described below to pattern the semiconductor structure body 10. Accordingly, the processes can be fewer than when another mask for patterning the semiconductor structure body 10 is formed.

As shown in FIG. 7, the method for manufacturing the semiconductor element of the embodiment includes a process of etching the semiconductor structure body 10 by using the second carbon film 30 as the second mask to form a groove 70 in the semiconductor structure body 10. After multiple element parts are formed on one substrate by the processes described above, the groove 70 is formed between the multiple element parts. For example, the groove 70 is formed by removing the insulating film 40 by dry etching using a gas including fluorine, followed by removing the semiconductor structure body 10 by dry etching using a gas including chlorine. In the process of forming the groove 70, the first p-side electrode 61 can be protected by covering, with the second carbon film 30 used as the second mask, the first p-side electrode 61 that is exposed from the insulating film 40.

In the process of forming the second carbon film 30, the ratio of carbon in sp³ hybridized orbitals in the second carbon film 30 can be set to be greater than the ratio of carbon in sp² hybridized orbitals in the second carbon film 30 by the control of the second bias voltage. For example, the ratio of carbon in sp³ hybridized orbitals in the second carbon film 30 can be set to be greater than the ratio of carbon in sp² hybridized orbitals by setting the second bias voltage to be not more than −40 V, favorably not more than −60 V, and more favorably not more than −100 V. Accordingly, similarly to the first carbon film 20 described above, the second carbon film 30 has stronger characteristics of diamond than graphite, and the hardness of the second carbon film 30 is high. Therefore, the second carbon film 30 is not easily etched when the second carbon film 30 is used as the second mask. Accordingly, when the second carbon film 30 is used as the second mask, the second carbon film 30 can be formed thinly, and the time of the process of forming the second carbon film 30 can be reduced. For example, the etching rate of the second carbon film 30 can be not more than 1/50 of the etching rate of the gallium nitride.

By setting the first bias voltage to be higher than the second bias voltage, the ratio of carbon in sp³ hybridized orbitals in the second carbon film 30 exceeds the ratio of carbon in sp³ hybridized orbitals in the first carbon film 20. Accordingly, the second carbon film 30 has a higher hardness than the first carbon film 20, and for the same etching conditions, is more difficult to etch than the first carbon film 20. Accordingly, the thickness of the second mask can be set to be less than the thickness of the first mask.

In other words, the thickness of the second carbon film 30 formed in the process of forming the second carbon film 30 can be set to be less than the thickness of the first carbon film 20 formed in the process of forming the first carbon film 20. The time of the process of forming the second carbon film 30 can be reduced thereby. For example, the thickness of the second carbon film 30 can be not less than 1 nm and not more than 200 nm.

The semiconductor structure body 10 is divided into multiple element parts by the groove 70. In the process of forming the groove 70, the upper surface of the substrate 100 may be exposed at the bottom of the groove 70, or the n-side layer 11 may remain below the groove 70.

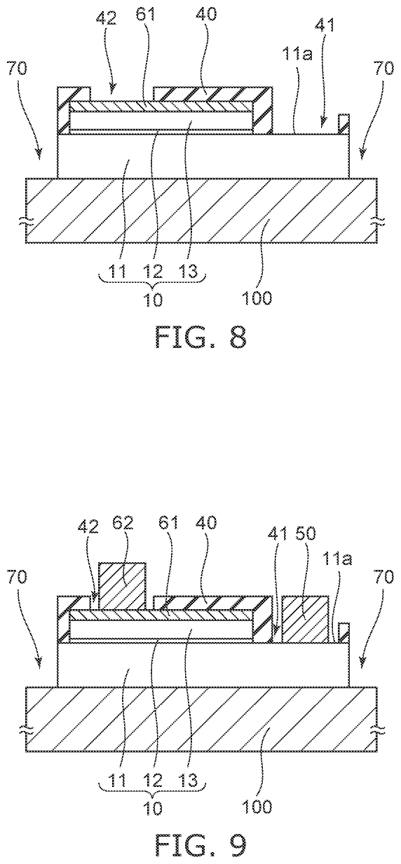

After the process of forming the groove 70, the method for manufacturing the semiconductor element of the embodiment includes a process of removing the second carbon film 30 as shown in FIG. 8. For example, the second carbon film 30 can be easily removed by ashing using oxygen plasma.

After the process of removing the second carbon film 30, the method for manufacturing the semiconductor element of the embodiment includes a process of forming an n-side electrode 50 on the portion 11a of the n-side layer 11 exposed in the first opening 41 as shown in FIG. 9. The n-side electrode 50 contacts the surface of the portion 11a of the n-side layer 11 and is electrically connected with the n-side layer 11.

After the process of removing the second carbon film 30, the method for manufacturing the semiconductor element of the embodiment also includes a process of forming a second p-side electrode 62 on the first p-side electrode 61 exposed in the second opening 42. The second p-side electrode 62 contacts the first p-side electrode 61 and is electrically connected with the p-side layer 13 via the first p-side electrode 61. The second p-side electrode 62 may be formed simultaneously with the n-side electrode 50.

As described above, in the process of forming the second carbon film 30, carbon is easily incorporated into the surface of the portion 11a of the n-side layer 11, and the electrical resistance of the surface of the portion 11a of the n-side layer 11 is easily reduced. Accordingly, according to the embodiment, the contact resistance between the n-side electrode 50 and the portion 11a of the n-side layer 11 can be easily reduced.

### Experimental Examples

A gallium nitride layer that included an n-type impurity, an active layer, and a gallium nitride layer that included a p-type impurity were formed in this order as the semiconductor structure body 10 on the substrate 100 made of sapphire, after which the electrical resistance of the surface of the gallium nitride layer including the p-type impurity was measured. The measured value at this time was 1.884×10⁷ (Ω·cm²). Subsequently, the first carbon film 20 was formed on the surface of the gallium nitride layer including the p-type impurity by vapor deposition utilizing carbon ions generated by an arc discharge without introducing a gas to a discharge space that was a vacuum as described above. The first bias voltage at this time was set to −20 V. Subsequently, the first carbon film 20 was removed by ashing using oxygen plasma. After the first carbon film 20 was removed, the electrical resistance of the surface of the gallium nitride layer including the p-type impurity that was in contact with the first carbon film 20 was measured using a surface resistance meter. The measured value at this time was 1.050×10⁷ (Ω·cm²), which was less than the electrical resistance of the surface of the gallium nitride layer including the p-type impurity before forming the first carbon film 20.

Also, a gallium nitride layer that included an n-type impurity, an active layer, and a gallium nitride layer that included a p-type impurity were formed in this order as the semiconductor structure body 10 on the substrate 100 made of sapphire. Subsequently, the gallium nitride layer including the p-type impurity and the active layer were removed, a portion of the gallium nitride layer including the n-type impurity was exposed, and the electrical resistance of the exposed surface of the gallium nitride layer including the n-type impurity was measured. The measured value at this time was 3.062×10² (Ω·cm²). Subsequently, the second carbon film 30 was formed on the surface of the gallium nitride layer including the n-type impurity by vapor deposition utilizing carbon ions generated by an arc discharge without introducing a gas to a discharge space that was a vacuum as described above. The second bias voltage at this time was set to −180 V. Subsequently, the second carbon film 30 was removed by ashing using oxygen plasma. After the second carbon film 30 was removed, the electrical resistance of the surface of the gallium nitride layer including the n-type impurity that was in contact with the second carbon film 30 was measured using a surface resistance meter. The measured value at this time was 1.500×10² (Ω·cm²), which was less than the electrical resistance of the surface of the gallium nitride layer including the n-type impurity before forming the second carbon film 30.

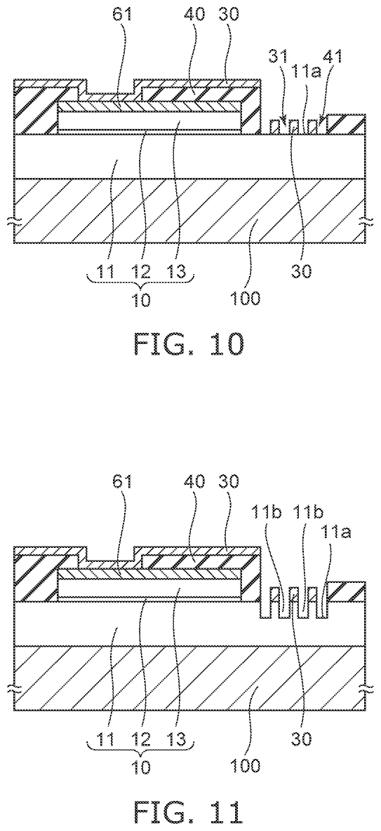

A method for manufacturing a semiconductor element according to a modification of the embodiment will now be described with reference to FIGS. 10 to 12. The modification of the embodiment differs from the embodiment in that multiple recesses 11b are formed in the portion 11a of the n-side layer 11 after etching the p-side layer 13 and the active layer 12 to expose the portion 11a of the n-side layer 11 from under the p-side layer 13 and the active layer 12. According to the modification of the embodiment, the n-side electrode 50 continuously covers the surface of the n-side layer 11 defining the recesses 11b of the portion 11a of the n-side layer 11.

After the insulating film 40 is formed, the second carbon film 30 is formed as shown in FIG. 10. According to the modification of the embodiment, the second carbon film 30 includes multiple openings 31 that expose the portion 11a of the n-side layer 11.

Subsequently, the portion 11a of the n-side layer 11 exposed in the multiple openings 31 of the second carbon film 30 is removed in the process of etching the semiconductor structure body 10 by using the second carbon film 30 as the second mask. Thereby, as shown in FIG. 11, the multiple recesses 11b are formed in the portion 11a of the n-side layer 11.

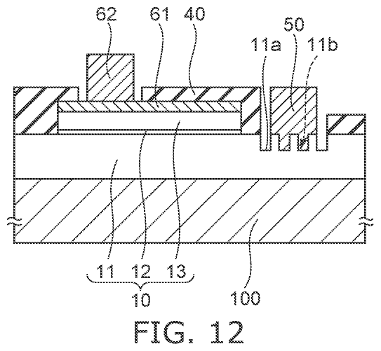

Subsequently, in the process of forming the n-side electrode 50, the n-side electrode 50 continuously covers the surface of the n-side layer 11 defining the multiple recesses 11b on the portion 11a of the n-side layer 11 as shown in FIG. 12. The n-side electrode 50 is located in the recesses 11b formed in the portion 11a of the n-side layer 11. Accordingly, the contact area between the n-side electrode 50 and the n-side layer 11 can be greater than when the n-side electrode 50 contacts a surface of the n-side layer 11 having no recesses, and the contact resistance between the n-side electrode 50 and the n-side layer 11 can be reduced. Also, the adhesion between the n-side electrode 50 and the n-side layer 11 can be improved.

Although example embodiments are described above in which the first carbon film 20 and the second carbon film 30 also are utilized as masks for etching the semiconductor structure body 10, the first carbon film 20 may be used only to reduce the electrical resistance of the p-side layer 13, and the second carbon film 30 may be used only to reduce the electrical resistance of the n-side layer 11. That is, masks other than the first and second carbon films 20 and 30 may be used to etch the semiconductor structure body 10.

What is claimed is:

1. A method for manufacturing a semiconductor element, the method comprising:
preparing a semiconductor structure body that comprises a p-side layer and an n-side layer;
forming a first carbon film on the p-side layer by vapor deposition, the vapor deposition utilizing carbon ions generated by an arc discharge without introducing a gas to a discharge space, the discharge space being a vacuum;
forming a second carbon film on the n-side layer by the vapor deposition;
removing the first carbon film; and
removing the second carbon film; wherein:
a first bias voltage during the forming of the first carbon film on the p-side layer is higher than a second bias voltage during the forming of the second carbon film on the n-side layer.

2. The method according to claim 1, wherein:
a hydrogen composition ratio of the first carbon film is not more than 1%, and a hydrogen composition ratio of the second carbon film is not more than 1%.

3. The method according to claim 1, wherein:
the p-side layer is located on the n-side layer; and
in the first carbon film, a ratio of carbon in sp³ hybridized orbitals is greater than a ratio of carbon in sp² hybridized orbitals; and
the method further comprises exposing a portion of the n-side layer from under the p-side layer by etching the p-side layer by using the first carbon film as a first mask.

4. The method according to claim 3, wherein:
the second carbon film is continuously formed above the p-side layer and on the portion of the n-side layer exposed from under the p-side layer;
in the second carbon film, a ratio of carbon in sp³ hybridized orbitals is greater than a ratio of carbon in sp² hybridized orbitals; and
the method further comprises etching the semiconductor structure body by using the second carbon film as a second mask to form a groove in the semiconductor structure body.

5. The method according to claim 4, wherein:
a thickness of the second carbon film formed in the forming of the second carbon film is less than a thickness of the first carbon film formed in the forming of the first carbon film.

6. The method according to claim 4, further comprising:
after the removing of the second carbon film, forming an n-side electrode on said portion of the n-side layer.

7. The method according to claim 6, wherein:
in the forming of the second carbon film, the second carbon film includes a plurality of openings in which said portion of the n-side layer is exposed;
the etching of the semiconductor structure body by using the second carbon film as the second mask includes forming a plurality of recesses in the portion of the n-side layer by removing the portion of the n-side layer exposed in the plurality of openings of the second carbon film; and
the n-side electrode continuously covers a surface of the n-side layer defining the plurality of recesses on the portion of the n-side layer.

8. The method according to claim 1, wherein:
the first bias voltage is not less than −40 V and not more than −10 V.

9. The method according to claim 1, wherein:
the second bias voltage is not less than −200 V and not more than −140 V.
